(19) United States
(12) Patent Application Publication
(10) Pub. No.: US 2003/0113998 A1
(43) Pub. Date: Jun. 19, 2003

(54) Flex tab for use in stacking packaged integrated circuit chips

(76) Inventor: Andrew C. Ross, Ramona, CA (US)

Correspondence Address: STETINA BRUNDA GARRED & BRUCKER, 75 ENTERPRISE, SUITE 250, ALISO VIEJO, CA, 92656, US

(21) Appl. No.: 10/024,389

(22) Filed: Dec. 17, 2001

(51) Int. Cl. H01L 21/44

(52) U.S. Cl. 438/678

(57) ABSTRACT

A connector for use in a chip stack including at least first and second stacked packaged chips which each comprise a package body having a plurality of leads extending therefrom. The connector comprises a substrate which is preferably fabricated from an insulating material. Attached to the substrate are a plurality of flex tabs which extend in spaced relation to each other, and are each preferably fabricated from a conductive material such as aluminum. The flex tabs are each shaped to define an arcuately contoured first portion which is electrically connectable to a respective one of the leads of the first packaged chip, and an integral, generally flat second portion which extends along a portion of the substrate and is electrically connectable to a corresponding one of the leads of the second packaged chip.

### CROSS-REFERENCE TO RELATED APPLICATIONS

(Not Applicable)

### STATEMENT RE: FEDERALLY SPONSORED RESEARCH/DEVELOPMENT

(Not Applicable)

### BACKGROUND OF THE INVENTION

The present invention relates generally to integrated circuit chip stacks, and more particularly to a chip stack including one or more flex tab connectors for use in making electrical connections between corresponding leads of stacked packaged chips such as TSOP devices or TQFP devices.

Multiple techniques are currently employed in the prior art to increase memory capacity on a printed circuit board or PCB. Such techniques include the use of larger memory chips, if available, and increasing the size of the circuit board for purposes of allowing the same to accommodate more memory devices or chips. Perhaps one of the most commonly used techniques to increase memory capacity is the stacking of memory devices into a vertical chip stack, sometimes referred to as 3-D packaging or Z-Stacking. In the Z-Stacking process, from two to as many as eight memory devices or other integrated circuit chips are interconnected in a single component (i.e., a chip stack) which is mountable to the “footprint” typically used for a single packaged chip.

In the Z-Stacking process, the packaged chips must, in addition to being formed into a stack, be electrically interconnected to each other in a desired manner. In certain chip stacks including TSOP (thin small outline package) or TQFP packaged chips, it is often desirable to create a discrete electrical connection between an individual lead of a first, lower packaged chip and a corresponding individual lead of a second, upper packaged chip stacked on top of the first packaged chip. It is also often desirable to create electrical connections between groups of the leads of the first packaged chip with one or more of the leads of the second packaged chip.

Currently used approaches to facilitate such electrical connection include the bending of a selected lead of the second, upper packaged chip down to within close proximity of the corresponding lead of the first, lower packaged chip, and thereafter soldering the leads to each other. Another currently used technique is to simply solder a jumper wire between the selected pair of leads of the first and second packaged chips. However, these prior art interconnection techniques do not provide an easy and reliable solution for achieving the desired electrical interconnection between the packaged chips of the chip stack. The present invention addresses this deficiency by providing a flex tab connector for effectuating the electrical connection between any lead or leads on a lower, first packaged chip and a corresponding lead or leads on a second packaged chip stacked thereupon. The connector of the present invention may also be used to facilitate additional electrical connections to external circuitry. These, and other advantages of the present invention, will be discussed in more detail below.

### BRIEF SUMMARY OF THE INVENTION

In accordance with the present invention, there is provided a connector for use in a chip stack including at least first and second packaged chips which are stacked upon each other. Each of the packaged chips with which the present connector is used will typically be a TSOP (thin small outline package) device or a TQFP device which each comprise a package body having a plurality of S or gull-wing leads extending therefrom. The connector of the present invention comprises a rectangularly configured substrate which defines opposed, generally planar top and bottom surfaces and is fabricated from an insulating material. A preferred material for the substrate is a polyamide film. The connector further comprises a plurality of flex tabs which are attached to the substrate in spaced relation to each other. Each of the flex tabs is fabricated from a conductive material such as aluminum.

In the present connector, each of the flex tabs is shaped to define an arcuate first portion and an integral, generally flat second portion which is attached to and extends along a portion of the top surface of the substrate. The arcuate first portions of the flex tabs are disposed along a common longitudinal peripheral edge segment of the substrate. Also preferably included in the connector is a conductive metal layer which is attached to and extends along at least a portion of the bottom surface of the substrate. As such, the conductive layer extends in opposed relation to at least some of the second portions of the flex tabs extending along the top surface of the substrate. It is contemplated that the conductive layer may be electrically connected to one or more of the second portions of the flex tab via respective ones of conductive vias which extend through the substrate.

The connector is used by electrically connecting the first portions of the flex tabs to respective ones of the leads of the first (lower) packaged chip of the chip stack. As will be recognized, in the chip stack assembly process, the first portions of the flex tabs must initially be aligned with respective ones of the leads of the first packaged chip. Subsequent to the stacking of the second (upper) packaged chip upon the first packaged chip such that the leads of the second packaged chip are aligned with respective ones of the second portions of the flex tabs, the second portions of the flex tabs are electrically connected to respective ones of the leads of the second packaged chip. The electrical connection of the flex tabs to the leads of the first and second packaged chips is preferably accomplished through the use of solder or a conductive epoxy.

If the first and second packaged chips of the chip stack each comprise a TSOP device having leads extending from each of the opposed longitudinal sides of the packaged body, two connectors will be used to complete the assembly of such chip stack, with each connector being used to electrically interconnect the leads extending along corresponding longitudinal sides of the package bodies. If TQFP devices are included in the chip stack wherein leads extend from each of four sides of a generally square package body, four connectors will be employed in the chip stack, with each connector being used to electrically interconnect the leads extending along corresponding sides of the package bodies.

Those of ordinary skill in the art will recognize that the connectors of the present invention may be used in the assembly of chip stacks including more than two stacked packaged chips. Advantageously, the conductive layer preferably included in each of the connectors allows selected ones of the leads of the first packaged chip to be electrically connected to selected ones of the leads of the second packaged chip, or to external circuitry.

### BRIEF DESCRIPTION OF THE DRAWINGS

These, as well as other features of the present invention, will become more apparent upon reference to the drawings wherein:

FIG. 1 is a partial side-elevational view of a chip stack assembled using a flex tab connector constructed in accordance with the present invention;

FIG. 2 is a top plan view of the present connector; and

FIG. 3 is a top perspective view of the connector shown in FIG. 2.

### DETAILED DESCRIPTION OF THE INVENTION

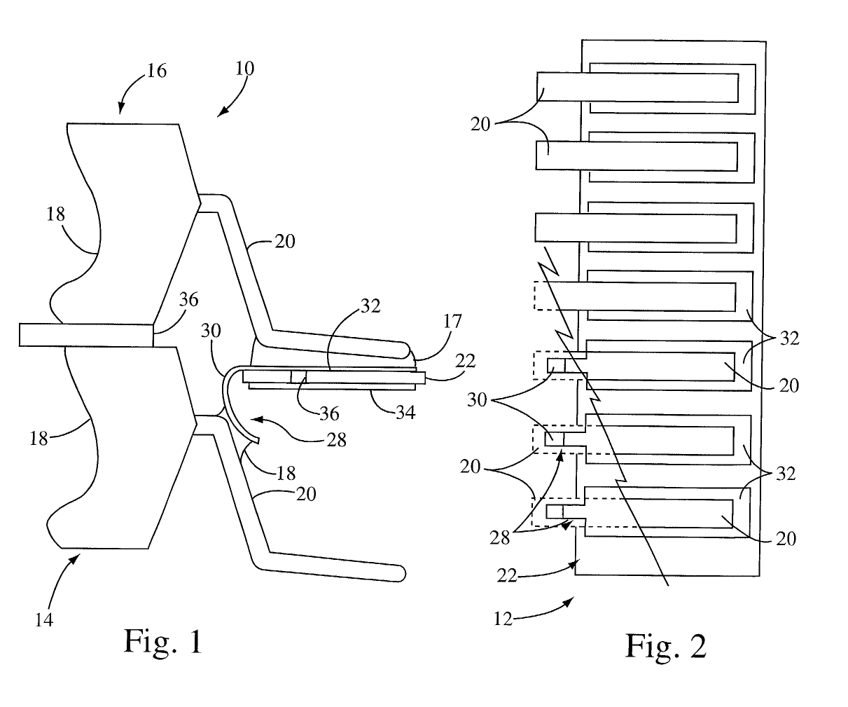

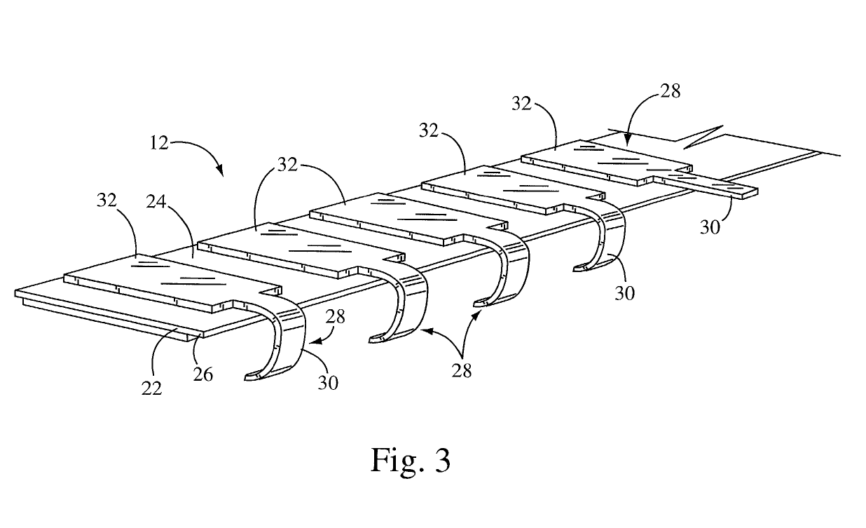

Referring now to the drawings wherein the showings are for purposes of illustrating a preferred embodiment of the present invention only, and not for purposes of limiting the same, FIG. 1 partially illustrates a chip stack 10 assembled through the use of the flex tab connector 12 constructed in accordance with the present invention. The connector 12 is shown in FIGS. 2 and 3. As will be discussed in more detail below, the connector 12 is used to achieve a desired pattern of electrical interconnection between a first, lower packaged chip 14 and a second, upper packaged chip 16 which is identically configured to the first packaged chip 14 and stacked thereon. The first and second packaged chips 14, 16 of the chip stack 10 each comprise either a TSOP (thin small outline package) device or a TQFP device. In this regard, the first and second packaged chips 14, 16 each comprise a package body 18 having a plurality of gull-wing leads 20 protruding therefrom. If the first and second packaged chips 14, 16 each comprise a TSOP device, each package body 18 will typically be rectangularly configured, with the leads 20 protruding from each of the opposed longitudinal sides thereof. If the first and second package chips 14, 16 each comprise a TQFP device, the package body 18 will typically have a generally square configuration, with the leads 20 protruding from each of the four sides defined thereby.

The connector 12 of the present invention preferably comprises a rectangularly configured substrate 22 which defines a generally planar top surface 24, a generally planar bottom surface 26, an opposed pair of longitudinal peripheral edge segments, and an opposed pair of lateral peripheral edge segments. The substrate 22 is fabricated from an insulating material, with a preferred material for the substrate 22 being a polyamide film.

In addition to the substrate 22, the connector 12 comprises a plurality of identically configured flex tabs 28 which are attached to the substrate 22. Each of the flex tabs 28 is fabricated from a conductive material such as aluminum, and is shaped to define an arcuate first portion 30 which transitions into an integral, generally flat and rectangularly configured second portion 32. The second portion 32 extends along and is attached to the top surface 24 of the substrate 22. The flex tabs 28 are attached to the substrate 22 so as to be equidistantly spaced from each other. The first portions 30 of the flex tabs 28 extend along a common longitudinal peripheral edge segment of the substrate 22, with the second portions 32 being sized so as to extend along the top surface 24 to almost the remaining, opposite longitudinal peripheral edge segment of the substrate 22.

As seen in FIG. 3, the flex tabs 28 of the connector 12 are initially formed such that the first portion 30 and the second portion 32 are linearly aligned, i.e., extend in co-planar relation to each other. An exemplary “pre-bent” flex tab 28 is shown in FIG. 3. Subsequent to the formation of the flex tabs 28 upon the top surface 24 of the substrate 22, the second portions 32 are bent to assume the desired arcuate configurations.

As best seen in FIG. 1, the connector 12 may further comprise a conductive layer 34 which is attached to and extends along at least a portion of the bottom surface 26 of the substrate 22. The conductive layer 34 is preferably fabricated from a metal material, and is rectangularly configured so as to extend along a substantial portion of the bottom surface 26. Thus, the conductive layer 34 extends in opposed relation to the second portions 32 of the flex tabs 28 extending along the top surface 24 of the substrate 22. As further seen in FIG. 1, it is contemplated that the conductive layer 34 may be electrically connected to one or more of the second portions 32 of the flex tabs 28 via respective ones of conductive vias 36 which extend through the substrate 22.

The connector 12 is used by electrically connecting the first portions 30 of the flex tabs 28 to respective ones of the leads 20 of the lower, first packaged chip 14 of the chip stack 10. As will be recognized, in assembling the chip stack 10, the first portions 30 of the flex tabs 28 must initially be aligned with respective ones of the leads 20 of the first packaged chip 14. Subsequent to the electrical connection of the first portions 30 of the flex tabs 28 to the leads 20 of the first packaged chip 14, the second packaged chip 16 is stacked upon the first packaged chip 14. As also seen in FIG. 1, a layer 36 of epoxy may be applied between the package bodies 18 of the first and second packaged chips 14, 16 to maintain the same in fixed relation to each other. The upper, second packaged chip 16 is oriented upon the lower, first packaged chip 14 such that the leads 20 of the second packaged chip 16 are aligned with respective ones of the second portions 32 of the flex tabs 28. Thereafter, the second portions 32 of the flex tabs 28 are electrically connected to respective ones of the leads 20 of the second packaged chip 16.

In the chip stack 10, the electrical connection of the flex tabs 28 to the leads 20 of the first and second packaged chips 14, 16 is preferably accomplished through the use of solder or a conductive epoxy. As further seen in FIG. 1, the first portions 30 of the flex tabs 28 of the connector 12 are preferably bent and “cropped” so as to extend in close proximity to and overlap an upper portion of the vertically extending segment of a corresponding lead 20 of the first packaged chip 14. The second portion 32 of each flex tab 28 is itself sized so as to extend along substantially the entire length of the horizontally extending segment of the corresponding lead 20 of the second packaged chip 16.

If the first and second packaged chips 14, 16 of the chip stack 10 each comprise a TSOP device having leads 20 extending from each of the opposed longitudinal sides of the package body 18, two connectors 12 will be used to complete the assembly of such chip stack 10, with each connector 12 being used to electrically interconnect the leads 20 extending along corresponding longitudinal sides of the package bodies 18. If the first and second packaged chips 14, 16 each comprise a TQFP device wherein the leads 20 extend from each of the four sides of the generally square package body 18, four connectors 12 will be employed in the chip stack 10, with each connector 12 being used to electrically interconnect the leads 20 extending along corresponding sides of the package bodies 18.

Those of ordinary skill in the art will recognize that the connectors 12 of the present invention may be used in the assembly of chip stacks including more than two stacked packaged chips. The conductive layer 34 preferably included in each of the connectors 12 allows selected ones of the leads 20 of the first packaged chip 14 to be electrically connected to selected ones of the leads 20 of the second packaged chip 16, or to external circuitry. As will be recognized, the number of flex tabs 28 included on the substrate 22 of each connector 12 will be dependent upon the number of leads protruding from corresponding sides of the stacked packaged chips.

The flex tab connector 12 of the present invention provides an inexpensive solution to a manufacturing process for stacking and electrically connecting packaged chips. The connector 12 has a minimal impact on the outside dimensions of the chip stack assembled using the same, with the solder joints between the flex tabs 28 of the connector 12 and the corresponding leads of the stacked packaged chips being visible for assembly, thus providing a benefit for OEM manufacturers. The electrical interconnections facilitated by the connector 12 are also re-workable, thus eliminating the necessity to pre-process the packaged chips. Moreover, in any chip stack assembled through the use of the connectors 12, the packaged chips thereof are completely recoverable, provided that the package bodies thereof are not assembled to each other through the use of the layer 36 of the epoxy.

Additional modifications and improvements of the present invention may also be apparent to those of ordinary skill in the art. Thus, the particular combination of parts described and illustrated herein is intended to represent only certain embodiments of the present invention, and is not intended to serve as limitations of alternative devices within the spirit and scope of the invention.

1. A connector for use in a chip stack including at least first and second stacked packaged chips which each comprise a package body having a plurality of leads extending therefrom, the connector comprising:
a substrate fabricated from an insulating material; and
at least one flex tab attached to the substrate and fabricated from a conductive material;
the flex tab being shaped to define a first portion which is electrically connectable to one of the leads of the first packaged chip and an integral second portion which is electrically connectable to a corresponding one of the leads of the second packaged chip.

2. The connector of claim 1 wherein the substrate is fabricated from a polyamide film.

3. The connector of claim 1 wherein the flex tab is fabricated from aluminum.

4. The connector of claim 1 wherein:
the first portion of the flex tab has an arcuate configuration; and
the second portion of the flex tab has a generally flat configuration.

5. The connector of claim 4 wherein:
the substrate defines opposed, generally planar top and bottom surfaces; and
the second portion of the flex tab is disposed upon and extends along a portion of the top surface of the substrate.

6. The connector of claim 5 further comprising a conductive layer attached to and extending along at least a portion of the bottom surface of the substrate.

7. The connector of claim 6 wherein the conductive layer is electrically connected to the second portion of the flex tab by a conductive via extending through the substrate.

8. A connector for use in a chip stack including at least first and second stacked packaged chips which each comprise a package body having a plurality of leads extending therefrom, the connector comprising:
a substrate fabricated from an insulating material; and
a plurality of flex tabs attached to the substrate in spaced relation to each other, each of the flex tabs being fabricated from a conductive material;
the flex tabs each being shaped to define a first portion which is electrically connectable to a respective one of the leads of the first packaged chip and an integral second portion which is electrically connectable to a corresponding one of the leads of the second packaged chip.

9. The connector of claim 8 wherein the substrate is fabricated from a polyamide film.

10. The connector of claim 8 wherein each of the flex tabs is fabricated from aluminum.

11. The connector of claim 8 wherein:
the first portion of each of the flex tabs has an arcuate configuration; and
the second portion of each of the flex tabs has a generally flat configuration.

12. The connector of claim 11 wherein:
the substrate defines opposed, generally planar top and bottom surfaces; and
the second portion of each of the flex tabs is disposed upon and extends along a portion of the top surface of the substrate.

13. The connector of claim 12 further comprising a conductive layer attached to and extending along at least a portion of the bottom surface of the substrate.

14. The connector of claim 13 wherein the conductive layer is electrically connected to the second portion of at least two of the flex tabs by conductive vias extending through the substrate.

15. A chip stack comprising:
a first packaged chip comprising a package body having a plurality of leads extending therefrom;
a second packaged chip comprising a package body having a plurality of leads extending therefrom, the second packaged chip being stacked upon the first packaged chip such that the leads of the second packaged chip are aligned with respective ones of the leads of the first packaged chip; and
a connector electrically connecting the first and second packaged chips to each other and comprising:
a substrate fabricated from an insulating material;
at least one flex tab attached to the substrate and fabricated from a conductive material;
the flex tab being shaped to define a first portion which is electrically connected to one of the leads of the first packaged chip and an integral second portion which is electrically connected to a corresponding one of the leads of the second packaged chip.

16. The chip stack of claim 15 wherein the first and second packaged chips each comprise a TSOP device.

17. A chip stack comprising:
a first packaged chip comprising a package body having a plurality of leads extending therefrom;
a second packaged chip comprising a package body having a plurality of leads extending therefrom, the second packaged chip being stacked upon the first packaged chip such that the leads of the second packaged chip are aligned with respective ones of the leads of the first packaged chip; and
a connector electrically connecting the first and second packaged chips to each other and comprising:
a substrate fabricated from an insulating material; and
a plurality of flex tabs attached to the substrate in spaced relation to each other, each of the flex tabs being fabricated from a conductive material;
the flex tabs each being shaped to define a first portion which is electrically connected to a respective one of the leads of the first packaged chip and an integral second portion which is electrically connected to a corresponding one of the leads of the second packaged chip.

18. The chip stack of claim 17 wherein the first and second packaged chips each comprise a TSOP device.

19. A method for assembling a chip stack comprising at least first and second package chips which each include a package body having a plurality of leads extending therefrom, the method comprising the steps of:
a) pre-assembling a connector comprising:
a substrate fabricated from an insulating material; and
a plurality of flex tabs attached to the substrate in spaced relation to each other, each of the flex tabs being fabricated from a conductive material and shaped to define a first portion and an integral second portion;
b) aligning the first portions of the flex tabs with respective ones of the leads of the first packaged chip;
c) electrically connecting the first portions of the flex tabs to respective ones of the leads of the first packaged chip;
d) stacking the second packaged chip upon the first packaged chip such that the leads of the second packaged chip are aligned with respective ones of the first portions of the flex tabs; and
e) electrically connecting the second portions of the flex tabs to respective ones of the leads of the second packaged chip.

20. The method of claim 19 wherein steps (c) and (e) are accomplished through the use of a soldering process.
